(19) United States
(12) Patent Application Publication
(10) Pub. No.: US 2013/0194766 A1
(43) Pub. Date: Aug. 1, 2013

(54) SIGNAL FILTERING MOUNTING SCTRUCTURE

(71) Applicant: Po-Jung CHEN, Taoyuan County (TW)

(72) Inventor: Po-Jung CHEN, Taoyuan County (TW)

(73) Assignee: U.D.ELECTRONIC CORP., Taoyuan County (TW)

(21) Appl. No.: 13/362,216

(22) Filed: Jan. 31, 2012

(51) Int. Cl. H05K 7/06

(52) U.S. Cl. 361/782; 361/760

(57) ABSTRACT

A signal filter mounting structure includes a circuit board having two spaced lines of metal contacts, a box mounted on the circuit board between the two spaced lines of metal contacts and having two lines of upright bars arranged at opposing front and back sides thereof and a wire management groove defined between each two adjacent upright bars, and signal filters accommodated in the box in reversed directions, each signal filter including a magnetic coil and a plurality of conductor wires wound on the magnetic coil with the end portions thereof respectively extending out of the box through the wire management grooves and respectively soldered to the metal contacts of the circuit board.

### BACKGROUND OF THE INVENTION

1. Field of the Invention

The present invention relates to the signal filter mounting technology and more particularly, to a signal filter mounting structure, which uses a box to hold signal filters on a circuit board, enabling the end portions of the conductor wires of the signal filters to be respectively extended out of respective wire management grooves at opposing front and back sides of the box and soldered to respective metal contacts at the circuit board, saving much installation labor and cost and ensuring high soldering quality.

2. Description of the Related Art

Following fast development of computer technology, desk computers and notebook computers are well developed and widely used in different fields for different applications. It is the market trend to provide computers having high operating speed and small size. Further, network communication technology brings people closer, helping people to gather information about living, learning, working and recreational activities.

Further, to fit the market trend to create computers and electronic products having light, thin, short and small characteristics, electric connectors for computer and electronic product must be small-sized. Further, using electronic connectors in a computer must consider the problem of interfering noises that include internal noises and surrounding electromagnetic waves. Further, a RJ45 connector is for digital communication application. To eliminate signal interference, a network connector may have a filter module built therein to remove noises from incoming signal, enabling the filtered effective signal to be transmitted to an external control circuit interface for conversion into a serial data signal for processing in a data processing system.

FIG. 10 illustrates a conventional electrical network connector. According to this prior art design, the electrical network connector comprises a body A, an electrical module B, and a metal shield C. The body A comprises a first housing A1, a second housing A2 attached to the top side of the first housing A1, and a plurality of conducting terminals A21 mounted in the second housing A2 for bonding to an external circuit board. The electrical module B comprises a holder shell B1 mounted in the first housing A1, a circuit board B2 mounted in the holder shell B1, a plurality of curved contact terminals B21 bonded to the back side of the circuit board B2 and positioned in respective terminal grooves in the first housing A1, a plurality of mounting terminals B11 bonded to the circuit board B2 and downwardly extended out of the holder shell B1 for bonding to the external circuit board, a plurality of filter devices B22 mounted on the front side of the circuit board 132 and electrically connected between the curved contact terminals 1321 and the mounting terminals B11 for removing noises from the signal passing therethrough.

During installation of the filter devices B22, the end portions of the copper wires 13221 of the filter devices 1322, after removal of the insulation, are respectively pressed on the respective solder points B23 at the circuit board B2, and then electrically bonded to the respective solder points B23 by hand soldering or spot soldering. During the soldering operation, the end portions of the copper wires B221 may be forced out of position accidentally by an external force, causing inaccurate or poor soldering and affecting the soldering quality and yield rate. This conventional soldering method wastes much labor and cost.

Therefore, there is a strong demand for a signal filter mounting design, which eliminates the aforesaid problems.

### SUMMARY OF THE INVENTION

The present invention has been accomplished under the circumstances in view. It is therefore an object of the present invention to provide a signal filter mounting structure, which saves much soldering labor and cost, ensuring high quality soldering and high yield rate.

To achieve this and other objects of the present invention, a signal filter mounting structure comprises a circuit board, a box, and a plurality of signal filters. The box is mounted on the circuit board between two lines of metal contacts at the circuit board, comprising an accommodation chamber, a plurality of upright bars arranged in a line at each of opposing front and back sides relative to the accommodation chamber, and a plurality of wire management grooves respectively defined between each two adjacent ones of the upright bars at each of the two opposing front and back sides relative to the accommodation chamber. The signal filters are accommodated in the accommodation chamber of the box in reversed directions, each comprising a magnetic coil and a plurality of conductor wires wound on the magnetic coil. The end portions of the conductor wires of the signal filters being respectively extending out of the wire management grooves of the box and respectively soldered to the metal contacts of the circuit board.

Further, the circuit board can be made having an opening, for example, a mounting slot, broken hole or through hole configured to receive the box.

In an alternate form of the present invention, the signal filter mounting structure comprises a plurality of circuit boards symmetrically disposed at two sides, a box set between the circuit boards, and a plurality of signal filters mounted in the box with the end portions of the conductor wires thereof respectively extending out of respective wire management grooves at the opposite front and back sides of the box and respectively soldered to respective metal contacts of the circuit boards.

### BRIEF DESCRIPTION OF THE DRAWINGS

FIG. 1 is an exploded view of a signal filter mounting structure in accordance with a first embodiment of the present invention.

FIG. 2 is an assembly view of the first embodiment of the present invention, illustrating the signal filters set in the box before installation of the box in the circuit board.

FIG. 3 is an oblique elevation of the first embodiment of the present invention, illustrating the box fastened to the circuit board and the end portions of the conductor wires of the signal filters respectively soldered to the respective metal contacts of the circuit board.

FIG. 4 is an exploded view illustrating an application example of the signal filter mounting structure in an electrical network connector.

FIG. 5 corresponds to FIG. 4 when viewed from another angle.

FIG. 6 is a sectional assembly view, in an enlarged scale, of the electrical network connector shown in FIG. 4.

FIG. 7 is an exploded view of a signal filter mounting structure in accordance with a second embodiment of the present invention.

FIG. 8 is an elevational assembly view, in an enlarged scale, of the signal filter mounting structure in accordance with the second embodiment of the present invention.

FIG. 9 is an elevational assembly view of a signal filter mounting structure in accordance with a third embodiment of the present invention.

FIG. 10 is an exploded view of an electrical network connector constructed according to the prior art.

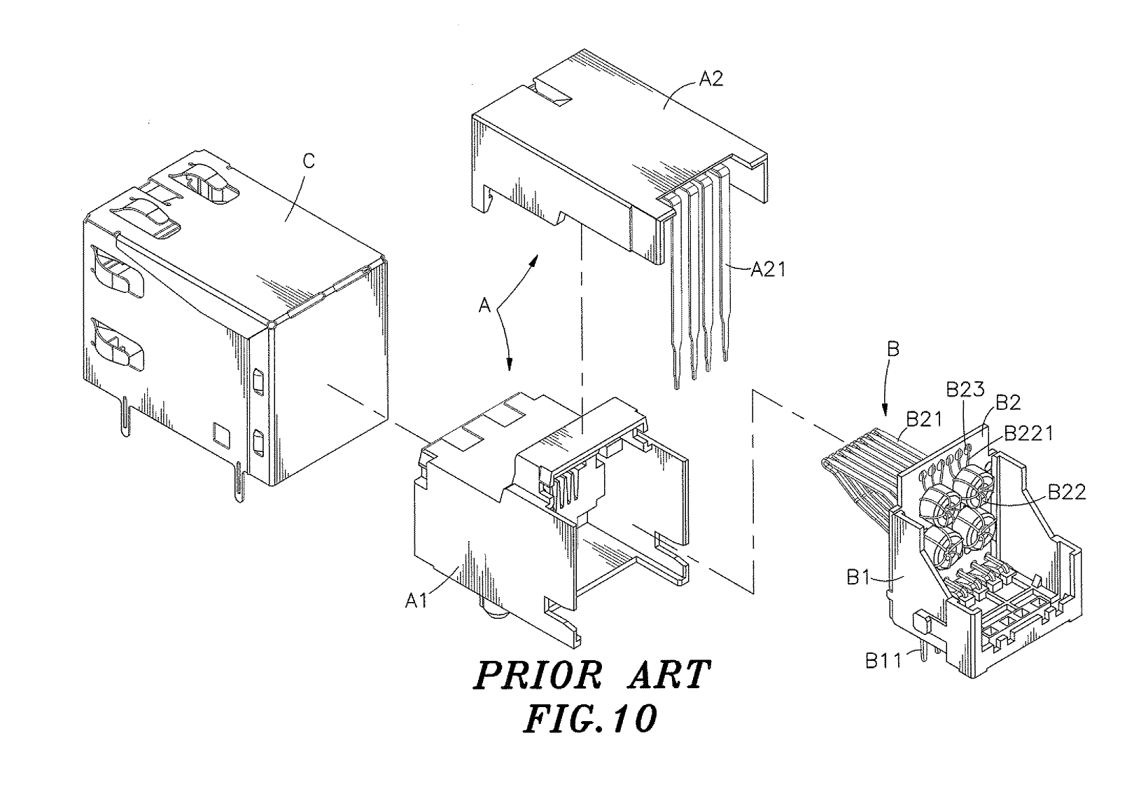

### DETAILED DESCRIPTION OF THE PREFERRED EMBODIMENT

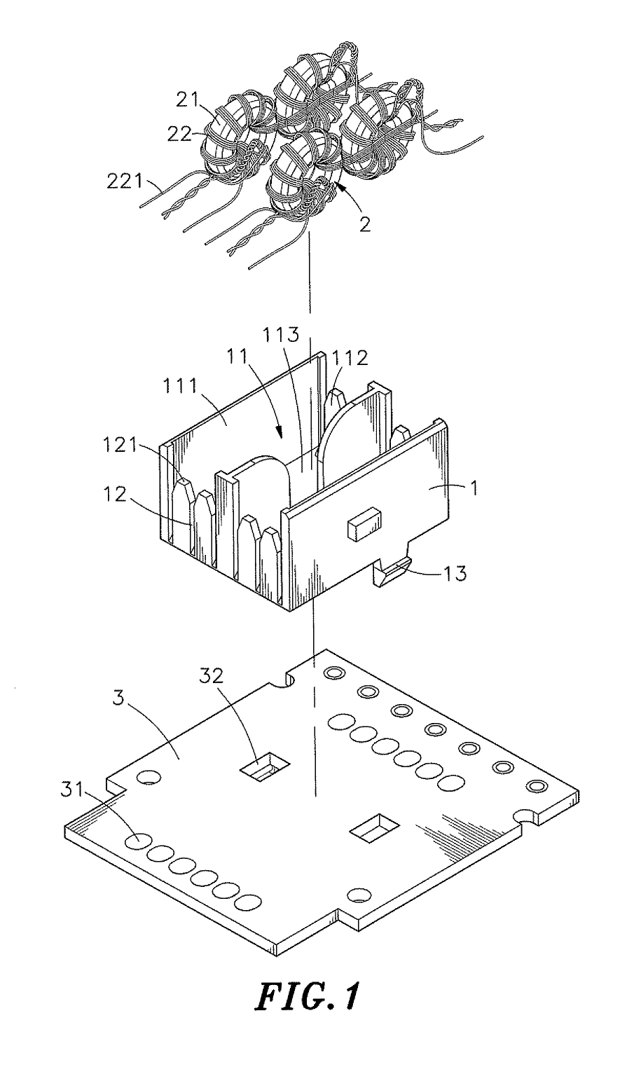

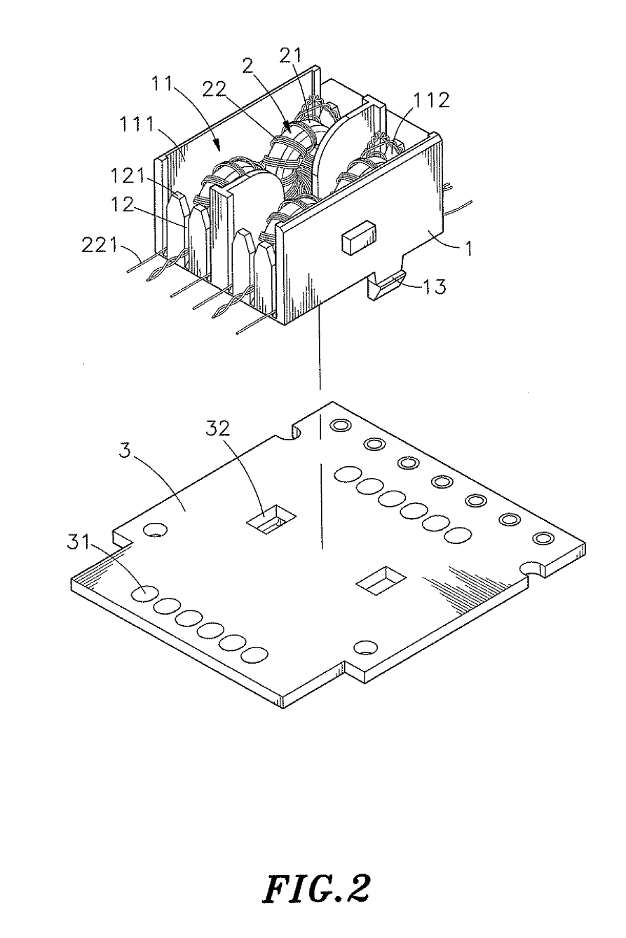

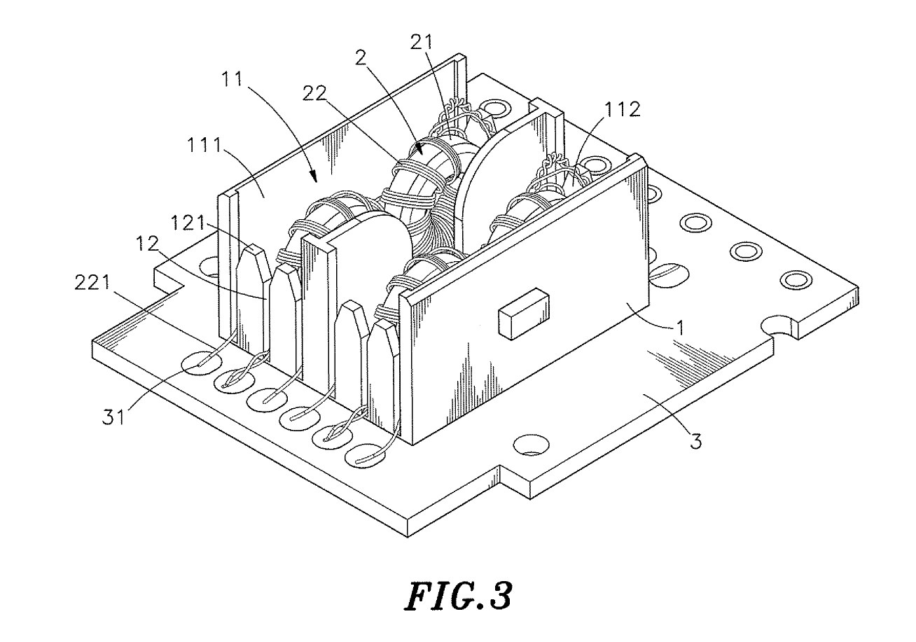

Referring to FIGS. 1, 2 and 3, a signal filter mounting structure in accordance with a first embodiment of the present invention is shown. As illustrated, the signal filer mounting structure comprises a box 1, a plurality of signal filters 2, and a circuit board 3.

The box 1 comprises an accommodation chamber 11 having a top opening 111 for accommodating the signal filters 2, a plurality of upright bars 121 arranged in line at each of opposing front and back sides 112 relative to the accommodation chamber 11, a plurality of wire management grooves 12 respectively defined between each two adjacent upright bars 121 in communication between the accommodation chamber 11 and the outside space, and a plurality of bottom hooks 13 symmetrically extended from the bottom edges of opposing left and right sides relative to the accommodation chamber 11.

The signal filters 2 are accommodated in the accommodation chamber 11 of the box 1, each comprising a magnetic coil 21, and a plurality of conductor wires 22 wound on the magnetic coil 21. Each conductor wire 22 has opposing front and rear ends thereof respectively terminating in a respective end portion 221 that consists of multiple metal filaments.

The circuit board 3 comprises a plurality of metal contacts 31 arranged in two lines on one (or each) of the opposing top and bottom walls thereof in perfect alignment (or in a staggered manner), and a plurality of hook holes 32 cut through the top and bottom walls between the two lines of metal contacts 31 for receiving the bottom hooks 13 of the box 1.

During installation, insert the magnetic coils 21 of the signal filters 2 through the top opening 111 into the accommodation chamber 1 and set the magnetic coils 21 in the accommodation chamber 11 of the box 1 properly in position in two reversed directions, and then pull the end portions 221 of the conductor wires 22 of the signal filters 2 along the bottom wall 113 of the accommodation chamber 11 to the outside of the box 1 through the wire management grooves 12 respectively, and then attach the box 1 to the top wall of the circuit board 3 between the two lines of contacts 31 to force the respective bottom hooks 13 into engagement with the hook holes 32 of the circuit board 3. Thus, the box 1 and the circuit board 3 are firmly secured together.

After installation of the box 1 with the signal filters 2 in the circuit board 3, the end portions 221 of the conductor wires 22 of the signal filters 2 are extended along the top wall of the circuit board 3 and respectively attached to the respective metal contacts 31 of the circuit board 3. Thereafter, the end portions 221 are respectively soldered to the respective metal contacts 31 by spot soldering or reflow soldering, electrically connecting the signal filters 2 to the circuit board 3. The structural design of the box 1 facilitating installing the signal filters 2, enabling the end portions 221 of the conductor wires 22 of the signal filters 2 to be straightened and kept apart from one another and then respectively extended through the wire management grooves 12 for bonding to the respective metal contacts 31 accurately. Thus, the use of the box 1 facilitates alignment and bonding between the end portions 221 and the metal contacts 31, saving much labor and cost and ensuring a high soldering quality and a high yield rate.

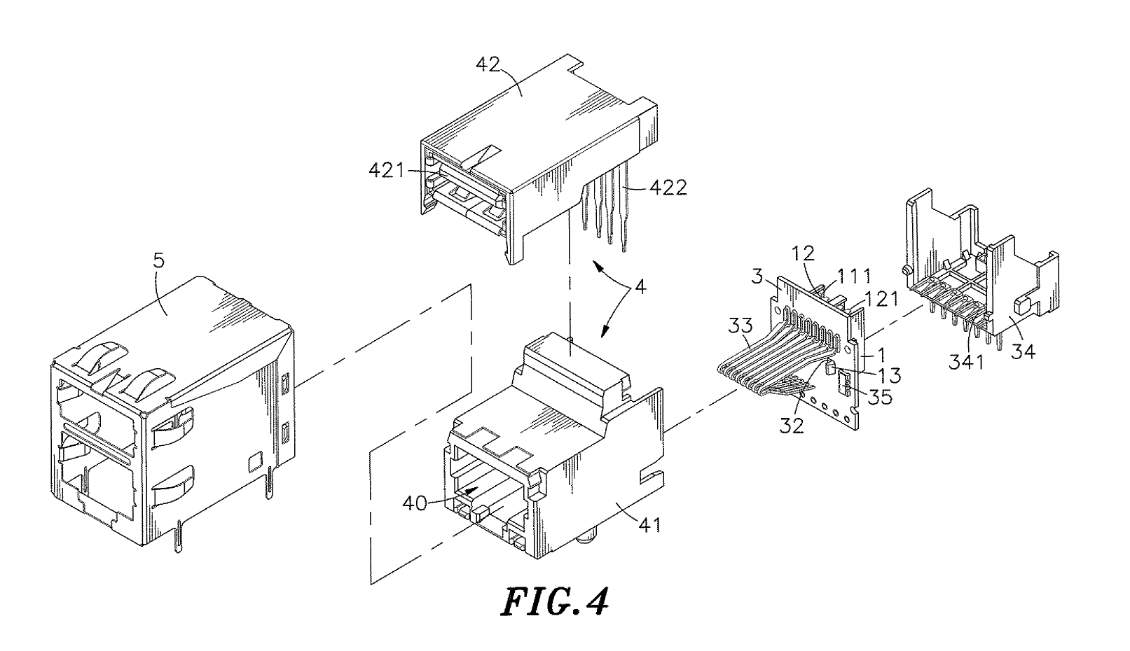

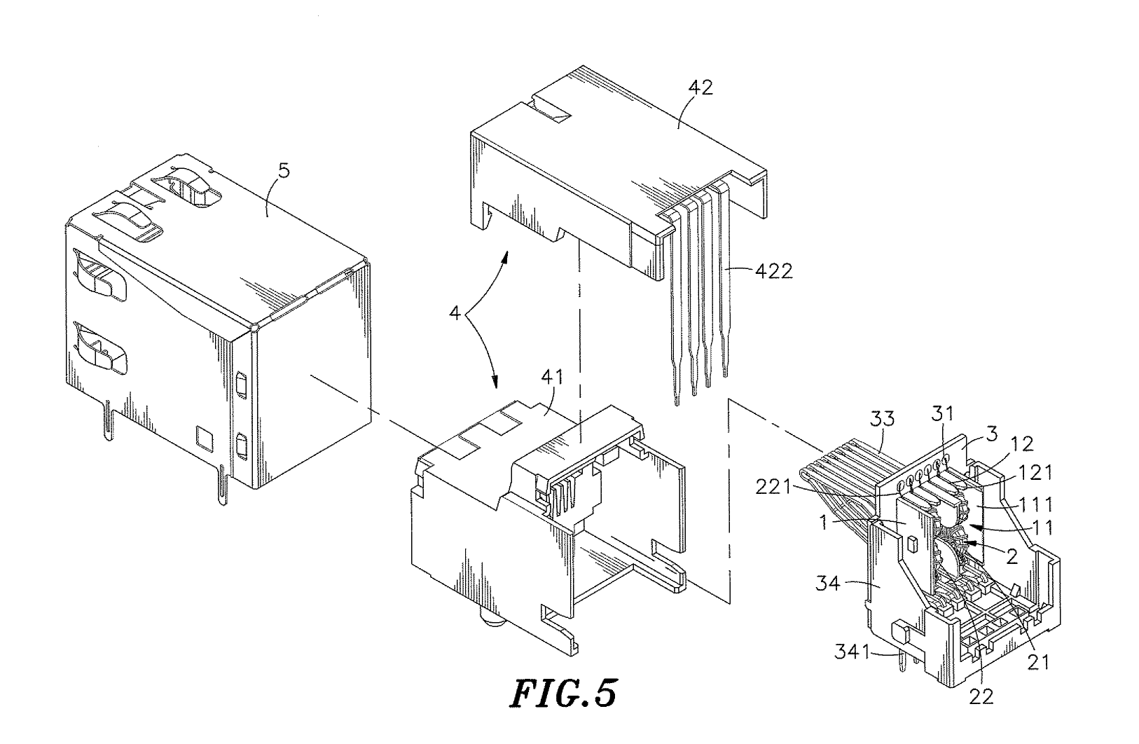

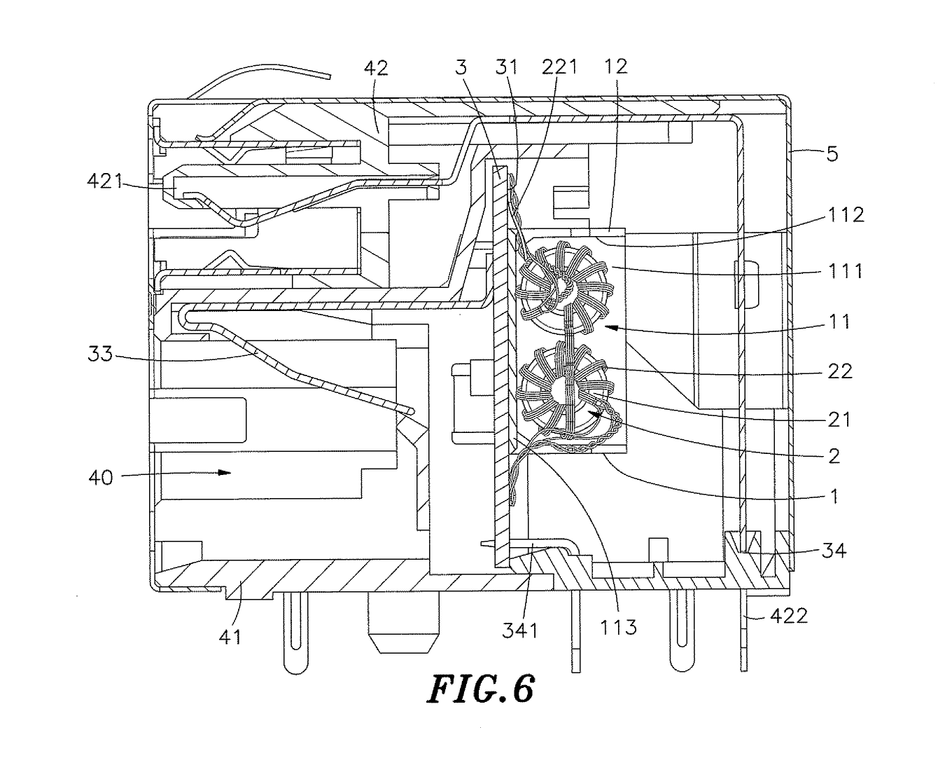

The design of the signal filter mounting structure in accordance with the present invention can be used in an interface card or electrical connector. FIGS. 4-6 illustrate an electrical network connector using the signal filter mounting structure. As illustrated, the signal filter structure of the box 1, signal filters 2 and circuit board 3 is assembled with a terminal holder 34, first and second conducting terminals 33;341 and at least one electronic component 35 to form a signal filter module that is mounted in an electrical network connector 4. The electrical network connector 4 comprises a first housing 41 defining a front receiving chamber 40, a second housing 42 attached to the top side of the first housing and defining therein a connection portion 421, a plurality of conducting terminals 422 mounted in the second housing 42, and a metal shield S surrounding the first housing 41 and the second housing 42.

The circuit board 3 of the signal filter module is mounted in the electrical network connector 4. The first conducting terminals 33 of the signal filter module are curved conducting terminals installed in one side of the circuit board 3 opposite to the box 1 and the signal filters 2 and electrically connected to the metal contacts 31 of one line of metal contacts 31 on the circuit board 3, with the middle curved portions thereof set in respective terminal grooves in the front receiving chamber 40 of the first housing 41. The terminal holder 34 is attached to the circuit board 3 adjacent to the box 1. The second conducting terminals 341 of the signal filter module are installed in the terminal holder 34 and respectively bonded to the metal contacts 31 of the other line of metal contacts 31 on the circuit board 3, and downwardly extending out of the bottom side of the terminal holder 34 for bonding to an external circuit board. Further, the circuit board 3 of the signal filter module has a circuit layout design. Further, the at least one electronic component 35 of the signal filter module can be a resistor network, capacitor, rectifier, and/or any other electronic device with wave-filtration function for removing noises from the transmitting signal to ensure signal transmission stability.

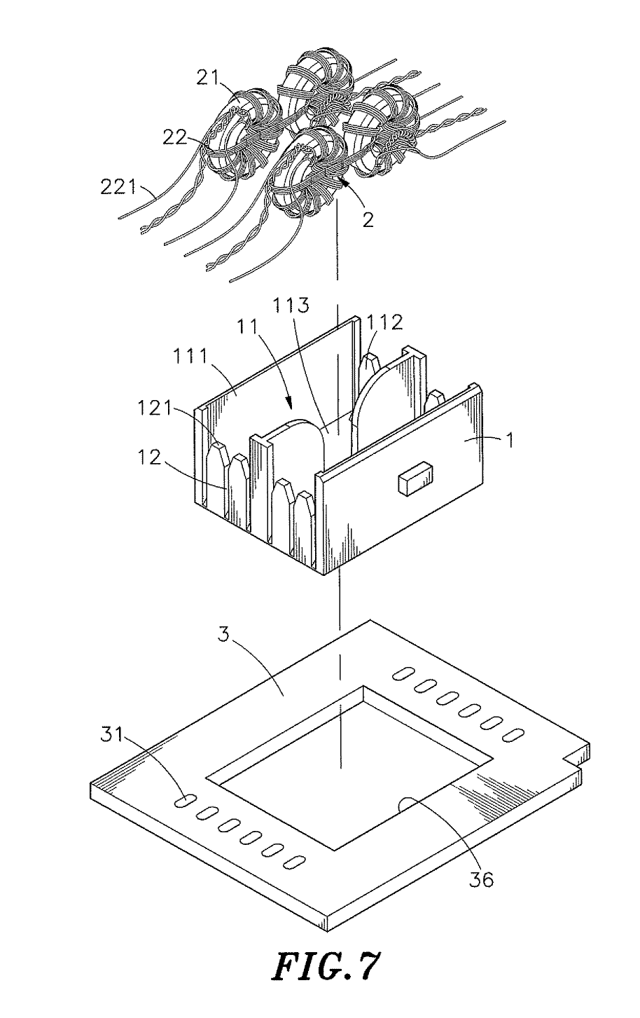

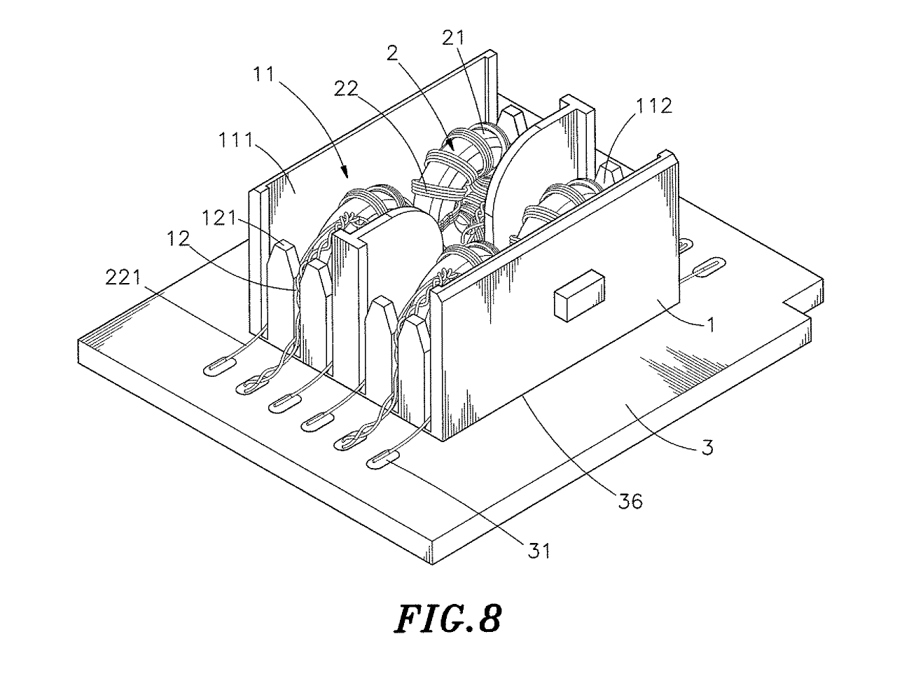

FIGS. 7 and 8 illustrate a signal filter mounting structure in accordance with a second embodiment of the present invention. According to this second embodiment, the signal filer mounting structure comprises a box 1, a plurality of signal filters 2, and a circuit board 3. The circuit board 3 comprises an opening 36 cut through the opposing top and bottom walls thereof on the middle, and a plurality of metal contacts 31 arranged in two lines at two opposite sides relative to the opening 36. The opening 36 can be a mounting slot, broken hole or through hole. The box 1 is configured for positioning in the opening 36 of the circuit board 3, eliminating the aforesaid bottom hooks 13. The signal filters 2 are set in the box 1 with the end portions 221 of the conductor wires 22 respectively extended out of respective wire management grooves 12 of the box 1 and respectively bonded to the metal contacts 31 of the circuit board 3.

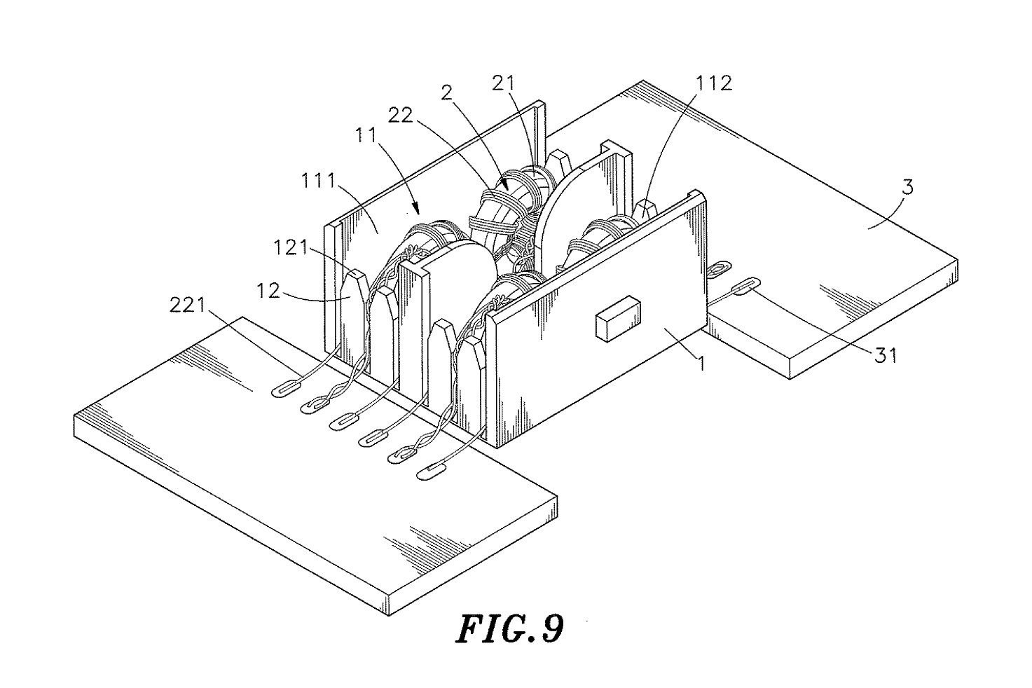

FIG. 9 illustrates a signal filter mounting structure in accordance with a third embodiment of the present invention. According to this third embodiment, the signal filter mounting structure comprises a box 1, a plurality of signal filters 2, and two circuit boards 3. Each circuit board 3 comprises a plurality of metal contacts 31 arranged in a line. The box 1 is set between the two circuit boards 3. The signal filters 2 are mounted in the box 1 with the end portions 221 of the conductor wires 22 thereof respectively extended out of respective wire management grooves 12 of the box 1 and respectively bonded to the metal contacts 31 of the two circuit boards 3.

In conclusion, the invention provides a signal filter mounting structure consisting of a box, a plurality of signal filters and at least one circuit board, as shown in FIGS. 1, 3, 8 and 9, wherein the signal filters 2 are mounted in the accommodation chamber 11 of the box 1 with the end portions 221 of the conductor wires 22 thereof respectively extending out of the wire management grooves 12 and straightened and kept apart from one another and then respectively bonded to the respective metal contacts 31 of the circuit board(s) 3.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A signal filter mounting structure, comprising:
a circuit board comprising two spaced lines of metal contacts;
a box mounted on said circuit board between said two spaced lines of metal contacts, said box comprising an accommodation chamber having a top opening, a plurality of upright bars arranged in a line at each of opposing front and back sides relative to said accommodation chamber, and a plurality of wire management grooves respectively defined between each two adjacent ones of said upright bars at each of the two opposing front and back sides relative to said accommodation chamber; and
a plurality of signal filters accommodated in said accommodation chamber of said box in reversed directions, each said signal filter comprising a magnetic coil and a plurality of conductor wires wound on said magnetic coil, each said conductor wire having opposing front and rear ends thereof respectively terminating in a respective end portion, the end portions of the conductor wires of said signal filters being respectively extending out of said wire management grooves and respectively soldered to said metal contacts of said circuit board.

2. The signal filter mounting structure as claimed in claim 1, wherein said circuit board comprises a plurality of hook holes spaced between said two spaced lines of metal contacts and symmetrically disposed at two opposite lateral sides relative to said box; said box comprises a plurality of bottom hooks respectively downwardly extended from two opposite lateral sides thereof and respectively hooked in said hook holes of said circuit board.

3. The signal filter mounting structure as claimed in claim 1, wherein said two spaced lines of metal contacts are arranged in a staggered manner.

4. A signal filter mounting structure, comprising:
a circuit board comprising an opening cut through opposing top and bottom sides thereof, and two lines of metal contacts arranged at two opposite sides relative to said opening;
a box mounted in said opening of said circuit board, said box comprising an accommodation chamber having a top opening, a plurality of upright bars arranged in a line at each of opposing front and back sides relative to said accommodation chamber, and a plurality of wire management grooves respectively defined between each two adjacent ones of said upright bars at each of the opposing front and back sides relative to said accommodation chamber; and
a plurality of signal filters accommodated in said accommodation chamber of said box in reversed directions, each said signal filter comprising a magnetic coil and a plurality of conductor wires wound on said magnetic coil, each said conductor wire having opposing front and rear ends thereof respectively terminating in a respective end portion, the end portions of the conductor wires of said signal filters being respectively extending out of said wire management grooves and respectively soldered to said metal contacts of said circuit board.

5. The signal filter mounting structure as claimed in claim 4, wherein said two lines of metal contacts are arranged in a staggered manner.

6. The signal filter mounting structure as claimed in claim 4, wherein the opening of said circuit board is configured in one of the forms of mounting slot, broken hole and through hole.

7. A signal filter mounting structure, comprising:
a plurality of circuit boards symmetrically disposed at two sides, each said circuit board comprising a plurality of metal contacts arranged in a line;
a box set between said circuit boards, said box comprising an accommodation chamber having a top opening, a plurality of upright bars arranged in a line at each of opposing front and back sides relative to said accommodation chamber, and a plurality of wire management grooves respectively defined between each two adjacent ones of said upright bars at each of the two opposing front and back sides relative to said accommodation chamber; and
a plurality of signal filters accommodated in said accommodation chamber of said box in reversed directions, each said signal filter comprising a magnetic coil and a plurality of conductor wires wound on said magnetic coil, each said conductor wire having opposing front and rear ends thereof respectively terminating in a respective end portion, the end portions of the conductor wires of said signal filters being respectively extending out of said wire management grooves and respectively soldered to the metal contacts of said circuit boards.

8. The signal filter mounting structure as claimed in claim 7, wherein the metal contacts at each circuit board at one side relative to said box are arranged in a staggered manner relative to the metal contacts at one corresponding circuit board at the opposite side relative to said box.
